(19) United States
(12) Patent Application Publication
(10) Pub. No.: US 2024/0250215 A1
(43) Pub. Date: Jul. 25, 2024

(54) SEMICONDUCTOR ELEMENT AND PRODUCTION METHOD THEREFOR

(71) Applicant: TDK CORPORATION, Tokyo (JP)

(72) Inventors: Kosuke TANAKA, Tokyo (JP); Masato SATO, Tokyo (JP); Kenta ONO, Tokyo (JP); Susumu TANIGUCHI, Tokyo (JP)

(73) Assignee: TDK CORPORATION, Tokyo (JP)

(21) Appl. No.: 18/561,449

(22) PCT Filed: Mar. 25, 2022
(86) PCT No.: PCT/JP2022/014686

§ 371 Date: Nov. 16, 2023

(30) Foreign Application Priority Data
May 20, 2021 (JP) 2021-085511

(51) Int. Cl. H01L 33/38; H01S 5/042

(52) U.S. Cl. CPC H01L 33/382; H01S 5/04256; H01L 2933/0016

(57) ABSTRACT

In the semiconductor element, a second electrode is higher than a first electrode, and the first electrode and the second electrode have substantially the same height positions of the upper surfaces. In the semiconductor element, since the first electrode and the second electrode can be formed at the same time, it is possible to form the semiconductor element including the first electrode and the second electrode by a small number of processes.

### TECHNICAL FIELD

The present disclosure relates to a semiconductor element and a production method therefor.

### BACKGROUND ART

In recent years, development of displays using a semiconductor element including a nitride semiconductor such as GaN as a light source has been advanced. The semiconductor element may be formed by sequentially stacking an n-type layer, an active layer, and a p-type layer made of a nitride semiconductor on a substrate. For example, one electrode (p-side electrode) of the semiconductor element is provided on the p-type layer located at the uppermost layer, and the other electrode (n-side electrode) is provided on the n-type layer partially exposed from the p-type layer and the active layer by etching removal.

As a result of the etching removal, a step portion is formed between the region where the p-side electrode is formed and the region where the n-side electrode is formed on the substrate, and the height position of the region where the n-side electrode is formed is lower than the height position of the region where the p-side electrode is formed.

Patent Literature 1 below discloses a technique of changing the thickness of a solder film provided on the p-side electrode and the thickness of a solder film provided on the n-side electrode (that is, a technique of making the thickness of the solder film provided on the n-side electrode thicker) in order to mount the semiconductor element having the step portion on a flat mounting substrate.

### CITATION LIST

### Patent Literature

Patent Literature 1: Japanese Patent Application Publication No. 2001-168444

### SUMMARY OF INVENTION

### Technical Problem

In the above-described semiconductor element according to the related art, it is difficult to form the solder film with high dimensional accuracy, and it is not easy to form the solder films having different thicknesses.

The inventors have made studies on thickening the p-side electrode and the n-side electrode to change the height of the electrode itself instead of changing the thickness of the solder films. However, even thick-film electrodes cannot be easily manufactured because the same manufacturing process needs to be repeated a plurality of times when the thick-film electrodes are formed separately.

An object of one aspect of the present disclosure is to provide a semiconductor element capable of easily forming thick-film electrodes having different heights, and a method of manufacturing the semiconductor element.

### Solution to Problem

A semiconductor element according to one aspect of the present disclosure includes a substrate having a laminated structure including a semiconductor layer, the substrate having a first region and a second region lower than the first region on a main surface, an insulating film covering the first region and the second region, the insulating film having a first through-hole provided in the first region and a second through-hole provided in the second region, a first thick-film electrode provided in the first region and extending in a normal direction of the main surface, the first thick-film electrode including a first conduction portion extending through the first through-hole and reaching the substrate, and a second thick-film electrode provided in the second region and extending in the normal direction of the main surface, the second thick-film electrode including a second conduction portion extending through the second through-hole and reaching the substrate, wherein an area of the second through-hole is smaller than an area of the first through-hole when viewed from a direction perpendicular to the main surface of the substrate and the second thick-film electrode is higher than the first thick-film electrode.

In the above-described semiconductor element, since the second thick-film electrode higher than the first thick-film electrode can be formed simultaneously with the first thick-film electrode, the first thick-film electrode and the second thick-film electrode can be formed by a small number of processes.

In the semiconductor element according to another aspect, 2d>w2 holds when d is a dimension of the second conduction portion in the direction perpendicular to the main surface of the substrate and w2 is a dimension of the second conduction portion in a direction parallel to the main surface of the substrate.

In the semiconductor element according to another aspect, w1>2T1 holds when w1 is a dimension of the first through-hole in a direction parallel to the main surface of the substrate and T1 is a dimension of the first thick-film electrode in the direction perpendicular to the main surface of the substrate.

In the semiconductor element according to another aspect, a plurality of the second through-holes are provided in the insulating film in the second region, and the second thick-film electrode includes a plurality of the second conduction portions respectively extending through the second through-hole and reaching the substrate.

In the semiconductor element according to another aspect, the total areas of the second through-holes are smaller than the area of the first through-hole when viewed from the direction perpendicular to the main surface of the substrate.

A method for manufacturing a semiconductor element according to one aspect of the present disclosure includes steps of preparing a substrate having a laminated structure including a semiconductor layer, the substrate having a first region and a second region lower than the first region on a main surface, forming an insulating film covering the first region and the second region, the insulating film having a first through-hole provided in the first region and a second through-hole provided in the second region, forming simultaneously a first thick-film electrode and a second thick-film electrode, the first thick-film electrode including a first conduction portion extending in a normal direction of the main surface in the first region, extending through the first through-hole, and reaching the substrate, and a second thick-film electrode including a second conduction portion extending in the normal direction of the main surface in the second region, extending through the second through-hole, and reaching the substrate, wherein an area of the second through-hole is smaller than an area of the first through-hole when viewed from a direction perpendicular to the main surface of the substrate, and the second thick-film electrode is higher than the first thick-film electrode.

### Advantageous Effects of Invention

According to various aspects of the present disclosure, a semiconductor element capable of easily forming thick-film electrodes having different heights and a method for manufacturing the semiconductor element are provided.

### BRIEF DESCRIPTION OF DRAWINGS

FIG. 1 is a schematic cross-sectional view showing a semiconductor element according to an embodiment.

FIG. 2 is a plan view showing the electrode shown in FIG. 1.

FIG. 3 (a) to (c) parts show respective steps in manufacturing the semiconductor element of FIG. 1.

FIG. 4 (a) to (c) parts show respective steps in manufacturing the semiconductor element of FIG. 1.

FIG. 5 (a) to (c) parts show respective steps in manufacturing the semiconductor element of FIG. 1.

FIG. 6 (a) and (b) parts show respective steps in manufacturing the semiconductor element shown in FIG. 1.

FIG. 7 (a) and (b) parts show steps in manufacturing a semiconductor element according to a conventional technique.

### DESCRIPTION OF EMBODIMENTS

Hereinafter, embodiments of the present disclosure will be described with reference to the accompanying drawings. In the description of the drawings, the same or equivalent elements are denoted by the same reference numerals, and redundant description is omitted.

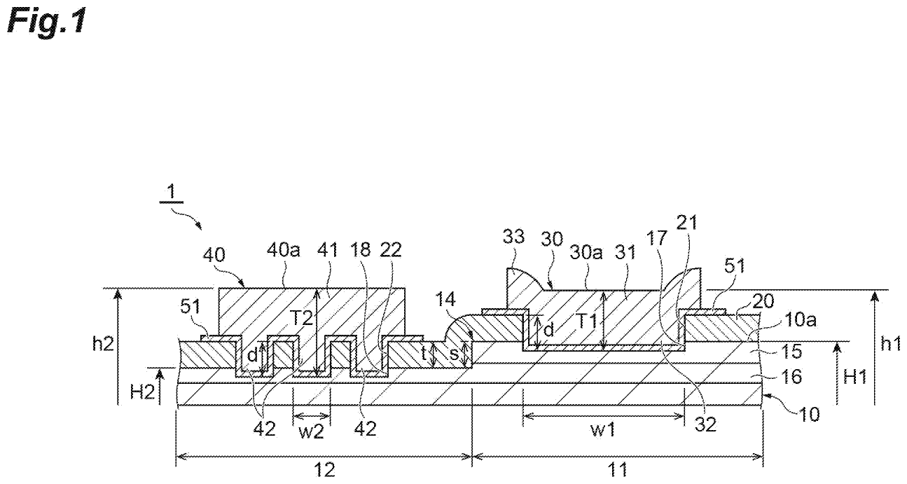

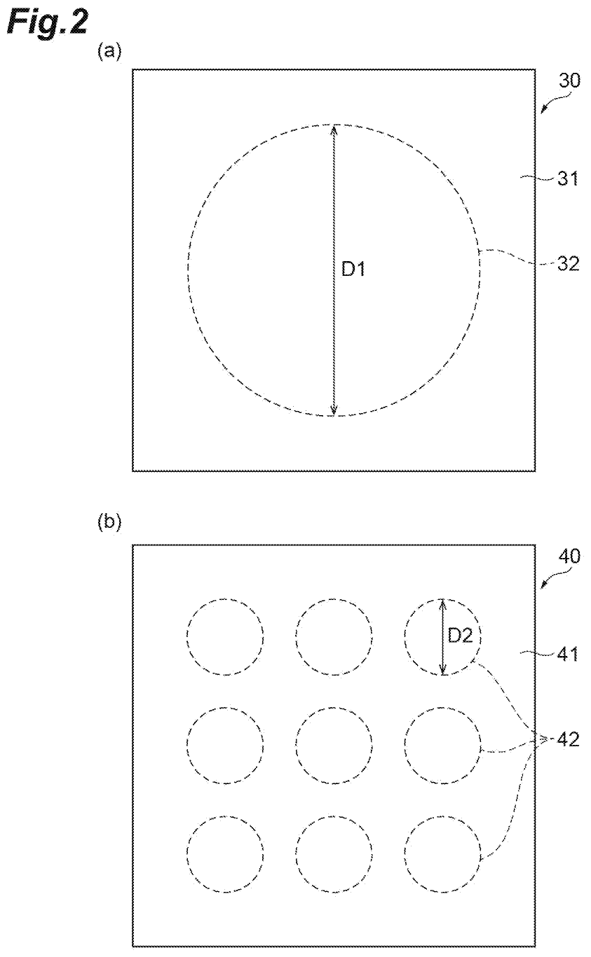

A semiconductor element 1 according to the embodiment will be described with reference to FIGS. 1 and 2. As shown in FIG. 1, the semiconductor element 1 according to the embodiment includes a substrate 10, an insulating film 20, and a pair of electrodes 30 and 40. The semiconductor element 1 is an element including, for example, a semiconductor such as GaN, AlGaN, GaAs, or Si and is, for example, an LED element or a semiconductor laser element.

The substrate 10 has a laminated (stacked) structure including a semiconductor layer. The substrate 10 has a main surface 10a, and the main surface 10a has a first region 11 and a second region 12. The first region 11 and the second region 12 have different height positions in a direction perpendicular to the main surface 10a. Specifically, the height position H2 of the second region 12 is lower than the height position H1 of the first region 11. In the present embodiment, both the first region 11 and the second region 12 are flat, and a step portion 14 is formed between the first region 11 and the second region 12 adjacent to each other. The step portion 14 can be formed by etching selectively away the substrate 10 in the second region 12. In the substrate 10, the main surface 10a in the first region 11 is composed of a p-type semiconductor layer 15, and the main surface 10a in the first region 11 is composed of an n-type semiconductor layer 16.

The insulating film 20 covers the main surface 10a of the substrate 10 entirely, and integrally covers the first region 11, the second region 12, and the step portion 14. The insulating film 20 is a film that inactivates the main surface 10a of the substrate 10 (so-called passivation film). The insulating film 20 may be made of an oxide or a nitride containing at least one element selected from the group consisting of Si, Al, Zr, Mg, Ta, Ti, and Y, or a resin. The insulating film 20 has a substantially uniform thickness t in the first region 11 and the second region 12 of the main surface 10a.

A through-hole 21 (first through-hole) is provided in a portion of the insulating film 20 covering the first region 11 of the main surface 10a. In the present embodiment, the through-hole 21 has a circular shape with a diameter D1 when viewed from a direction perpendicular to the main surface 10a. In the main surface 10a in the first region 11, a recess 17 having the same shape and size, when viewed from the direction perpendicular to the main surface 10a, as the through-hole 21 is provided at a position where the through-hole 21 of the insulating film 20 is provided. The recess 17 is connected to the through-hole 21 of the insulating film 20.

A plurality of through-holes 22 (second through-holes) are provided in a portion of the insulating film 20 covering the second region 12 of the main surface 10a. In the present embodiment, nine through-holes 22 aligned in three rows and three columns are provided. The number of through-holes 22 can be increased or decreased as appropriate, and may be one, for example. In the present embodiment, each of the through-holes 22 has a circular shape with a diameter D2 when viewed from a direction perpendicular to the main surface 10a. The diameter D2 is designed to be shorter than the diameter D1 of the through-hole 21 (D2<D1). In the second region 12 of the main surface 10a, a plurality of recesses 18 are provided at positions where the through-holes 22 of the insulating film 20 are provided. Each of the plurality of recesses 18 has the same shape and dimension as the through-hole 22 when viewed from the direction perpendicular to the main surface 10a. Each of the plurality of recesses 18 is connected to the through-hole 22 of the insulating film 20.

The pair of electrodes 30 and 40 includes a first electrode 30 (first thick-film electrode) provided in the first region 11 and a second electrode 40 (second thick-film electrode) provided in the second region 12. Each of the pair of electrodes 30 and 40 is made of a metal material, and is made of Cu in the present embodiment.

The first electrode 30 is a thick-film electrode extending in the normal direction of the main surface 10a of the substrate 10. The first electrode 30 includes a body portion 31 and a conduction portion 32 (first conduction portion). The body portion 31 is a portion located above the insulating film 20. In the present embodiment, as shown in (a) part of FIG. 2, the body portion 31 has a square shape when viewed from the direction perpendicular to the main surface 10a. The conduction portion 32 is a portion extending from the body portion 31 toward the substrate 10, and extends though the through-hole 21 of the insulating film 20 to reach the substrate 10. In the present embodiment, the conduction portion 32 is provided so as to completely fill the through-hole 21 of the insulating film 20 and the recess 17 of the substrate 10. Therefore, in the present embodiment, the conduction portion 32 has a cylindrical shape with the diameter D1. In the present embodiment, the body portion 31 of the first electrode 30 further includes a raised portion 33. The raised portion 33 is a portion raised from the upper surface 30a of the body portion 31, and is formed in an annular region corresponding to the edge of the through-hole 21 of the insulating film 20.

Like the first electrode 30, the second electrode 40 is a thick-film electrode extending in the normal direction of the main surface 10a of the substrate 10. The second electrode 40 includes a body portion 41 and a plurality of conduction portions 42 (second conduction portions). The body portion 41 is a portion located above the insulating film 20. In the present embodiment, as shown in (b) part of FIG. 2, the body portion 41 has a square shape when viewed from the direction perpendicular to the main surface 10a. The planar dimension of the body portion 41 of the second electrode 40 is designed to be the same as the planar dimension of the body portion 31 of the first electrode 30. The number of the plurality of conduction portions 42 is the same as the number of the through-holes 22 of the insulating film 20, and is nine in the present embodiment. Each of the conduction portions 42 is a portion extending from the body portion 41 toward the substrate 10, and extends in each of the through-hole 22 of the insulating film 20 to reach the substrate 10. In the present embodiment, each of the conduction portions 42 is provided so as to completely fill each through-hole 22 of the insulating film 20 and each recess portion 18 of the substrate 10. Therefore, in the present embodiment, each of the conduction portions 32 has a cylindrical shape with the diameter D2. The nine conduction portions 42 are arranged in three rows and three columns in the same manner as the through-holes 22. The heights of the first electrode 30 and the second electrode 40 can be defined respectively as lengths from the upper surfaces 30a and 40a of the body portions 31 and 41 to the lower ends of the conduction portions 32 and 42. In the semiconductor element 1, the height T2 of the second electrode 40 is higher than the height T1 of the first electrode 30. In the present embodiment, the height difference (T2−T1) between the height T1 of the first electrode 30 and the height T2 of the second electrode 40 is substantially the same as the step difference s of the step portion 14 of the substrate 10. Therefore, the height position h1 of the upper surface 30a of the first electrode 30 and the height position h2 of the upper surface 40a of the second electrode 40 substantially match each other. The difference between the height position h1 of the upper surface 30a of the first electrode 30 and the height position h2 of the upper surface 40a of the second electrode 40 may be 1 μm or less.

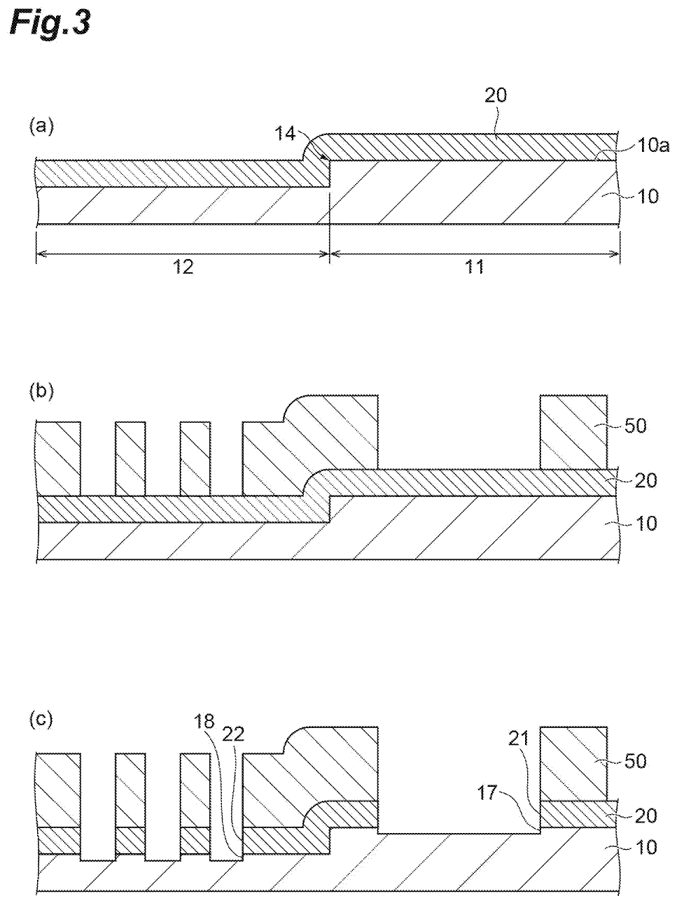

Next, a procedure for manufacturing the above-described semiconductor element 1 will be described with reference to FIGS. 3 to 6.

When manufacturing the semiconductor element 1, firstly, the substrate 10 is prepared as shown in (a) part of FIG. 3. The step portion 14 of the substrate 10 is formed by selectively etching away only the second region 12. The main surface 10a of the substrate 10 is subjected to passivation treatment, and the insulating film 20 that covers the entire main surface 10a is provided.

Next, as shown in (b) part of FIG. 3, a thick-film resist 50 is provided on the insulating film 20. The thick-film resist 50 is patterned such that regions where the through-holes 21 and 22 are formed are removed. For the thick-film resist 50, epoxy resin, acrylic resin, alkyd resin, or the like can be used.

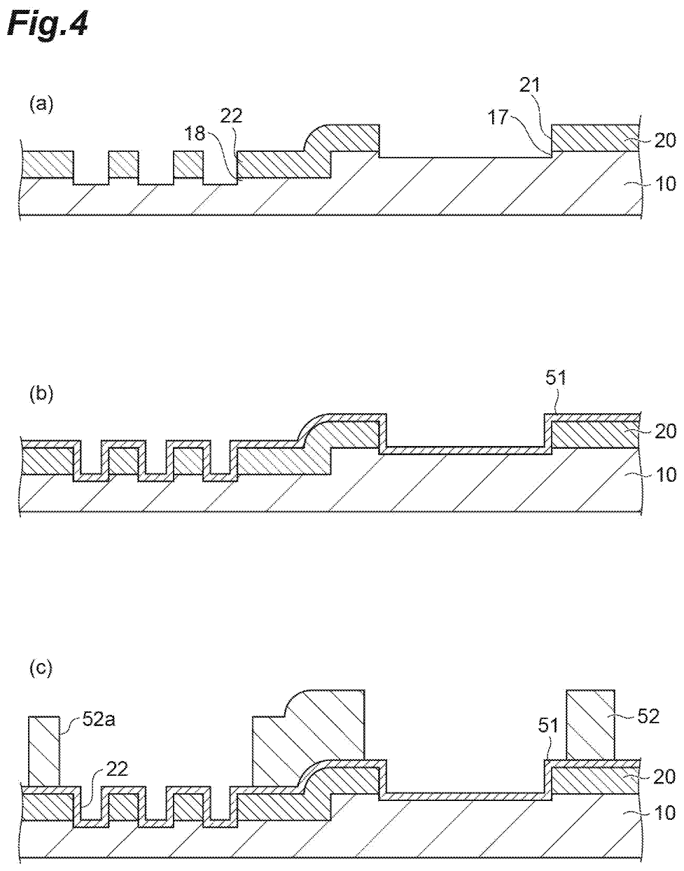

Subsequently, as shown in (c) part of FIG. 3, an etching process is performed using the thick-film resist 50. The through-holes 21 and 22 are formed in the insulating film 20 and recesses 17 and 18 are formed in the substrate 10 by the etching process. Then, as shown in (a) part of FIG. 4, the thick-film resist 50 is peeled off.

Next, as shown in (b) part of FIG. 4, an electrode film 51 is formed. In the present embodiment, the electrode film 51 is made of Cu. The electrode film 51 entirely covers the substrate 10 and the insulating film 20, and integrally covers the substrate 10 and the insulating film 20. More specifically, the electrode film 51 integrally covers the upper surface of the insulating film 20, the side surfaces of the through-holes 21 and 22, and the bottom surfaces and side surfaces of the recesses 17 and 18.

Subsequently, as shown in (c) part of FIG. 4, a thick-film resist 52 is provided on the insulating film 20 covered with the electrode film 51. As the thick-film resist 52, epoxy resin, acrylic resin, alkyd resin, or the like can be used. The thick-film resist 52 is patterned such that regions where the body portions 31 and 41 of the first electrode 30 and the second electrode 40 are formed are removed.

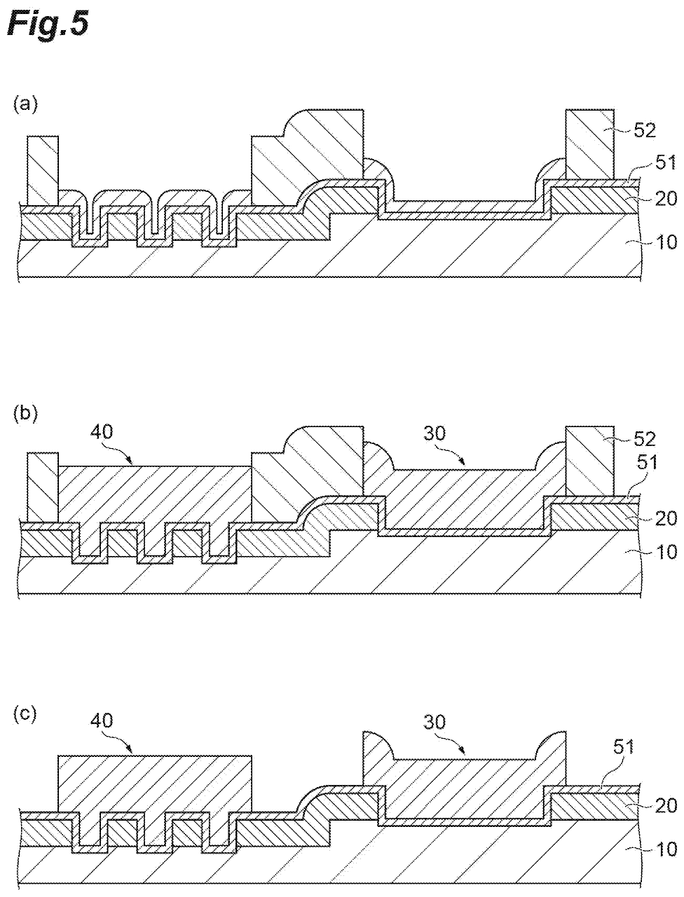

Then, as shown in (a) part of FIG. 5, plating is performed using the thick-film resist 52. Specifically, electrolytic plating of Cu is performed using the electrode film 51 as a seed. At this time, in the first region 11, Cu deposition starts from the inside of the through-hole 21 and the inside of the recess 17. On the other hand, in the second region 12, Cu deposition starts mainly from the edge of the through-hole 22, which is the upper surface of the insulating film 20. In the first region 11, the growth of the Cu plating progresses from the lower side toward the upper side, and the conduction portion 32 and the body portion 31 are formed in this order. In the second region 12, the growth of the Cu plating progresses from the start of deposition toward both the lower side and the upper side from the edge of the through-hole 22, and the body portion 41 is formed at a relatively early stage.

As the plating process proceeds, the first electrode 30 and the second electrode 40 having substantially the same height positions h1 and h2 of the upper surfaces 30a and 40a are completed at the same time. Since the height positions of the first electrode 30 and the second electrode 40 are aligned at the end of the plating process, it is not necessary to perform a polishing process for aligning the height positions.

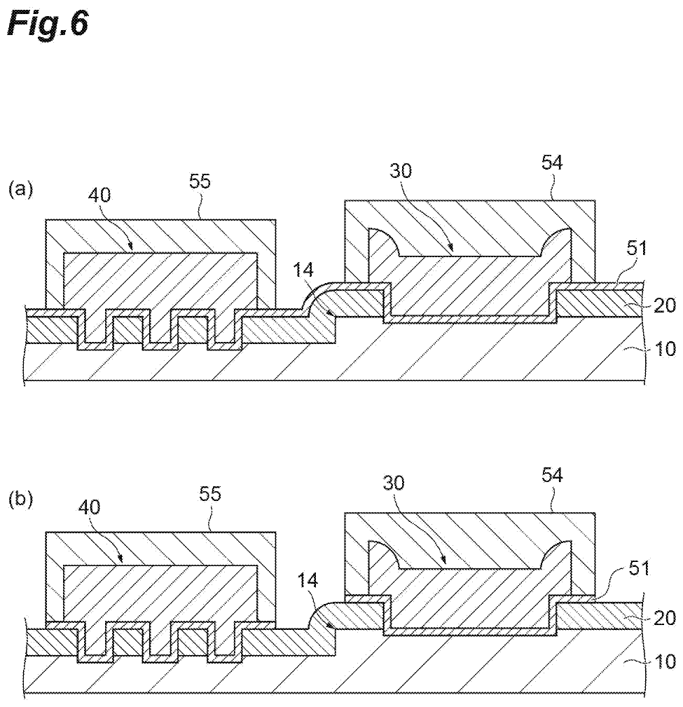

Thereafter, as shown in (c) part of FIG. 5, the thick-film resist 52 is peeled off. Further, as shown in (a) part of FIG. 6, a thick-film resist 54 and a thick-film resist 55 are provided. The thick-film resist 54 entirely covers the first electrode 30 provided in the first region 11 and the thick-film resist 55 entirely covers the second electrode 40 provided in the second region 12. As the thick-film resists 54 and 55, epoxy resin, acrylic resin, alkyd resin, or the like can be used. At this time, the step portion 14 of the substrate 10 is exposed from the thick-film resists 54 and 55. Then, as shown in (b) part of FIG. 6, etching processing is performed using the thick-film resists 54 and 55. By the etching process, the electrode film 51 provided on the step portion 14 of the substrate 10 is removed, and the first electrode 30 and the second electrode 40 are electrically separated. Finally, the thick-film resists 54 and 55 are peeled off to complete the semiconductor element 1 described above.

As described above, in the semiconductor element 1, the second electrode 40 is higher than the first electrode 30, and the first electrode 30 and the second electrode 40 have substantially the same height positions h1 and h2 of the upper surfaces 30a and 40a.

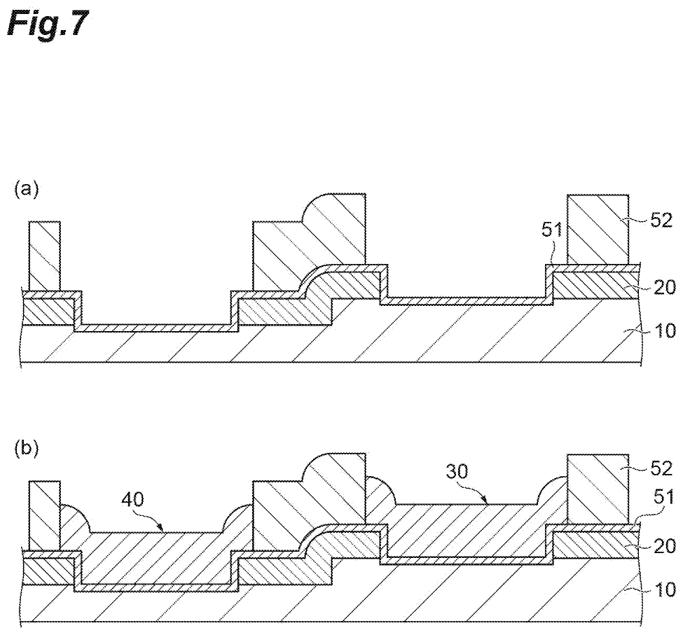

Here, as shown in (a) part of FIG. 7, when through-holes having the same dimensions are provided in the insulating film 20 in the first region 11 and the second region 12, since a height difference is generated in the upper surfaces 30a and 40a of the first electrode 30 and the second electrode 40 by the step difference s of the step portion 14, the height positions h1 and h2 of the upper surfaces 30a and 40a are greatly different as shown in (b) part of FIG. 7.

In the semiconductor element 1, since the first electrode 30 and the second electrode 40 having substantially the same height positions h1 and h2 of the upper surfaces 30a and 40a can be simultaneously formed, the semiconductor element 1 including the first electrode 30 and the second electrode 40 can be formed in a smaller number of processes.

In addition, in the semiconductor element 1, since the bonding areas between the second electrode 40 and both the insulating film 20 and the substrate 10 are increased by the plurality of conduction portions 42 of the second electrode 40, the adhesion of the second electrode 40 to the insulating film 20 and the substrate 10 is improved. Thus, the second electrode 40 is less likely to be detached from the insulating film 20 and the substrate 10, and the reliability of the semiconductor element 1 is improved. In the case that the plurality of through-holes 22 are provided in the insulating film 20, the total areas of the through-holes 22 (πD2²/4××9 in this embodiment) may be designed to be smaller than the area of the through-holes 21 (πD1²/4 in this embodiment). The total areas of the plurality of through-holes 22 may be the same as the area of the through-hole 21 or may be larger than the area of the through-hole 21.

Further, in the semiconductor element 1, 2d>w2 holds, when d is a dimension of the conduction portion 42 in the direction perpendicular to the main surface 10a of the substrate 10 (i.e., sum of a depth of the through-hole 22 and a depth of the recess 18) and w2 is a dimension of the conduction portion 42 in a direction parallel to the main surface 10a of the substrate 10 (i.e., D2). In this case, since Cu plating is easily deposited on the side surfaces of the through-holes 22, the first electrode 30 and the second electrode 40 having substantially the same height positions h1 and h2 of the upper surfaces 30a and 40a are easily completed at the same time. In addition, since the conduction portion 42 is elongated and enters deep into the insulating film 20 and the substrate 10, the adhesion of the second electrode 40 to the insulating film 20 and the substrate 10 is further improved.

In addition, in the semiconductor element 1, w1>2T1 holds, when w1 is a dimension of the through-hole 21 in the direction parallel to the main surface 10a of the substrate 10 and T1 is a dimension of the first electrode 30 in the direction perpendicular to the main surface 10a of the substrate 10 (i.e., height). In this case, the plating growth rate in the height direction of the first electrode 30 becomes relatively slow, and the first electrode 30 and the second electrode 40 having substantially the same height positions h1 and h2 of the upper surfaces 30a and 40a are easily completed at the same time.

Although the embodiment of the present disclosure have been described above, the present disclosure is not necessarily limited to the above-described embodiment, and various modifications can be made without departing from the scope of the present disclosure.

For example, the formation of the electrode is not limited to electroplating, and may be electroless plating, or may be another film formation method (for example, sputtering deposition). Further, the cross-sectional shape of the through-hole provided in the insulating film is not limited to a circular shape, and may be a polygonal shape such as a quadrangular shape or an elliptical shape. The shape of the body portion of the electrode is not limited to a square shape and may be a circular shape, a polygonal shape, or an elliptical shape when viewed from the direction perpendicular to the main surface of the substrate. Further, the conduction portion is not limited to a form in which the through-hole of the insulating film and the recess of the substrate are completely filled, but may be a form in which the through-hole and the recess portion are partially filled. In this case, a minute void may be formed in a space defined by the through-hole of the insulating film and the recess of the substrate.

### REFERENCE SIGNS LIST

1 semiconductor element
10 substrate
11 first region
12 second region
20 insulating film
21 and 22 through-hole
30 first electrode
32 conduction portion
40 second electrode
42 conduction portion

1. A semiconductor element comprising:
a substrate having a laminated structure including a semiconductor layer, the substrate having a first region and a second region lower than the first region on a main surface;
an insulating film covering the first region and the second region, the insulating film having a first through-hole provided in the first region and a second through-hole provided in the second region;
a first thick-film electrode provided in the first region and extending in a normal direction of the main surface, the first thick-film electrode including a first conduction portion extending through the first through-hole and reaching the substrate; and
a second thick-film electrode provided in the second region and extending in the normal direction of the main surface, the second thick-film electrode including a second conduction portion extending through the second through-hole and reaching the substrate,
wherein an area of the second through-hole is smaller than an area of the first through-hole when viewed from a direction perpendicular to the main surface of the substrate and the second thick-film electrode is higher than the first thick-film electrode.

2. The semiconductor element according to claim 1, wherein 2d>w2 holds when d is a dimension of the second conduction portion in the direction perpendicular to the main surface of the substrate and w2 is a dimension of the second conduction portion in a direction parallel to the main surface of the substrate.

3. The semiconductor element according to claim 1, wherein w1>2T1 holds when w1 is a dimension of the first through-hole in a direction parallel to the main surface of the substrate and T1 is a dimension of the first thick-film electrode in the direction perpendicular to the main surface of the substrate.

4. The semiconductor element according to claim 1, wherein a plurality of the second through-holes are provided in the insulating film in the second region, and
wherein the second thick-film electrode includes a plurality of the second conduction portions respectively extending through the second through-hole and reaching the substrate.

5. The semiconductor element according to claim 4, wherein the total areas of the second through-holes are smaller than the area of the first through-hole when viewed from the direction perpendicular to the main surface of the substrate.

6. A method for manufacturing a semiconductor element including steps of:
preparing a substrate having a laminated structure including a semiconductor layer, the substrate having a first region and a second region lower than the first region on a main surface;
forming an insulating film covering the first region and the second region, the insulating film having a first through-hole provided in the first region and a second through-hole provided in the second region;
forming simultaneously a first thick-film electrode and a second thick-film electrode, the first thick-film electrode including a first conduction portion extending in a normal direction of the main surface in the first region, extending through the first through-hole, and reaching the substrate, and a second thick-film electrode including a second conduction portion extending in the normal direction of the main surface in the second region, extending through the second through-hole, and reaching the substrate,
wherein an area of the second through-hole is smaller than an area of the first through-hole when viewed from a direction perpendicular to the main surface of the substrate, and the second thick-film electrode is higher than the first thick-film electrode.

7. A semiconductor element comprising:
a substrate having a laminated structure including a semiconductor layer, the substrate having a first region and a second region lower than the first region on a main surface;
an insulating film covering the first region and the second region, the insulating film having a first through-hole provided in the first region and a second through-hole provided in the second region;
a first thick-film electrode provided in the first region and extending in a normal direction of the main surface, the first thick-film electrode including a first conduction portion extending through the first through-hole and reaching the substrate; and
a second thick-film electrode provided in the second region and extending in the normal direction of the main surface, the second thick-film electrode including a second conduction portion extending through the second through-hole and reaching the substrate,
wherein the first through-hole has a substantially circular shape, a substantially polygonal shape or a substantially elliptical shape when viewed from a direction perpendicular to the main surface of the substrate, and the second through-hole has a substantially circular shape, a substantially polygonal shape or a substantially elliptical shape when viewed from the direction perpendicular to the main surface of the substrate, and
wherein an area of the second through-hole is smaller than an area of the first through-hole when viewed in a cross-section including the center of each of the first through-hole and the second through-hole and the second thick-film electrode is higher than the first thick-film electrode.

8. The semiconductor elements according to claim 1, wherein the insulating film is made of an oxide or a nitride containing at least one element selected from the group consisting of Si, Al, Zr, Mg, Ta, Ti, and Y, or a resin.

9. The semiconductor elements according to claim 1, wherein the insulating film has a substantially uniform thickness in the first region and the second region of the main surface of the substrate.

10. The semiconductor elements according to claim 7, wherein the insulating film is made of an oxide or a nitride containing at least one element selected from the group consisting of Si, Al, Zr, Mg, Ta, Ti, and Y, or a resin.

11. The semiconductor elements according to claim 7, wherein the insulating film has a substantially uniform thickness in the first region and the second region of the main surface of the substrate.

12. The method for manufacturing the semiconductor element according to claim 6, wherein the insulating film is made of an oxide or a nitride containing at least one element selected from the group consisting of Si, Al, Zr, Mg, Ta, Ti, and Y, or a resin.

13. The method for manufacturing the semiconductor element according to claim 6, wherein the insulating film has a substantially uniform thickness in the first region and the second region of the main surface of the substrate.
